(19) United States
(12) Patent Application Publication
(10) Pub. No.: US 2013/0187814 A1
(43) Pub. Date: Jul. 25, 2013

(54) Scanning Measurements On Generalized Grids

(71) Applicant: DireenTech, Inc., Colorado Springs, CO (US)

(72) Inventor: Randal Hugh Direen, Colorado Springs, CO (US)

(73) Assignee: DireenTech, Inc., Colorado Springs, CO (US)

(21) Appl. No.: 13/734,890

(22) Filed: Jan. 4, 2013

Related U.S. Application Data
(60) Provisional application No. 61/582,830, filed on Jan. 4, 2012.

(51) Int. Cl. G01R 29/10

(52) U.S. Cl. CPC G01R 29/10
USPC 343/703

(57) ABSTRACT

A scanning measurement apparatus and method comprising a device under test for receiving or transmitting a signal, a measurement probe, a robot for moving the device or the probe relative to one another to scan continuously over a two-dimensional planar, cylindrical or spherical surface in a three-dimensional space, and a controller for obtaining measurement samples at generalized grid points on the two-dimensional surface computing characteristic coefficients from the measured values, wherein the characteristic coefficients are recovered using a conjugate gradient method, using in part an unequally spaced fast Fourier transform or using a conjugate gradient method and an unequally spaced fast Fourier transform.

### CROSS-REFERENCE TO RELATED INVENTIONS

This application claims the benefit of provisional application No. 61/582,830, filed Jan. 4, 2012, the disclosure of which is hereby incorporated by reference herein.

### BACKGROUND OF THE INVENTION

1. Field of the Invention

This invention relates to electromagnetic and acoustic scanning measurements wherein a probe is used to collect measured data which is then processed to obtain antenna or microphone parameters, or images.

2. Description of the Background Art

Antenna characteristics may be determined by measuring antenna radiation patterns. The measurements are taken by scanning a probe over a surface intersecting the energy radiated by the antenna. FIGS. 1, 2 and 3 show example measurement setups over planar, cylindrical and spherical surfaces. In each of these figures a probe points toward the Antenna Under Test (AUT) as it scans over the surface of the geometry. The resulting measured data is then processed to determine antenna characteristics such as the radiation pattern, the antenna gain, the antenna directivity and a variety of other characteristics.

Obtaining the above mentioned antenna characteristics by scanning a probe over a surface and recording data is generally known in the industry as near-field antenna measurements. The definition of the near-field and far-field regions of an antenna, the theory for near-field antenna measurements and the history of near-field measurements are described in Wittmann; R. C., and Francis, M. H. “Near-field scanning measurements: theory and practice.”Modern Antenna Handbook. By Constantine A. Balanis. Hoboken, N.J.: J. Wiley & Sons, 2008; Hansen, J. E., Ed., Spherical Near-Field Antenna Measurements, London, U.K.: Peregrinus, 1988; Wittmann, R. C., and Stubenrauch, C. F. Spherical Near-Field Scanning: Experimental and Theoretical Studies: National Institute of Standards and Technology NISTIR 3955, July 1990 and Slater, Dan. Near-field Antenna Measurements. Boston: Artech House. 1991, the disclosures of each of which are hereby incorporated by reference herein.

More particularly, near-field antenna scanning is most commonly done on the surface of one of three standard geometries: planar (FIG. 1), spherical (FIG. 2) or cylindrical (FIG. 3). Scanning can be done over any surface in theory, but these three geometries are most commonly used because antenna parameters can be extracted from the data using efficient algorithms.

In these three geometries, a probe is used to measure the “probe-response” over some surface. Physical probes cannot (or can only approximately) measure the field of an antenna at a point in space. Instead of measuring the actual field of the probe at different points in space, the probe-response w(r) of the probe to the field of the radiating source is measured, it being understood that if the AUT is reciprocal, the same probe-response will be measured if the probe is radiating and the AUT is receiving. After the measurement has been finished, probe correction comprising data processing algorithms is performed to remove the effects of the probe from the measured data. Once the probe-response over the surface has been obtained by measurement, it can be expanded in an orthonormal set of modes:

$$w ( r ) • {\sum }_{n = 0}^{N} {c}_{n} {ϕ}_{n} ( r ) \qquad ( 1.1 )$$

where {φ [symbol] k(r)} are an orthonormal set of functions, cₙ are the coefficients, and the band limit N is chosen so that the summation approximates the probe response w(r) to the desired accuracy. The orthogonal functions {φ [symbol] k(r)} are determined from the scan geometry: for example, in the spherical geometry {φ [symbol] k(r)} are a set of vector spherical harmonics. Once the coefficients cₙ (implicitly defined by equation 1.1) are found, they can be used to determine the standard antenna parameters including the far-field antenna pattern. The coefficients cₙ completely characterize the antenna so they will be referred to as the antenna characteristic coefficients. It is sometimes convenient to define the characteristic coefficients cₙ in a variety of other ways. For example, it may better suit a particular problem to define the characteristic coefficients implicitly by the equation

$$w ( r ) = {\sum }_{n = 0}^{N} {u}_{n} {c}_{n} {ϕ}_{n} ( r )$$

where uₙ is a weighting function. (A particular weighting function, for example, would cause the characteristic coefficients to more directly relate to the far-field of the antenna.)

To determine the coefficients cₙ numerically, w(r) must be sampled at discrete locations that are sufficient for determining all N+1 coefficients. Equation (1.1) may, for example, be solved using Gaussian elimination. By straight Gaussian elimination, the order of operations necessary to find the coefficients cₙ is O(N [symbol] ) Common values of N, i.e., 10 [symbol] <N<10 [symbol] , have deterred people from considering Gaussian elimination as a useful method for obtaining the coefficients.

The nature of near-field theory allows for the calculation of cₙ to be sped up significantly with the fast Fourier transform (fft). For example, in planar and cylindrical scanning the order of operations necessary for calculating the coefficients becomes O(N log N) when the fft is employed. In the spherical case, it is also possible to use the fft in a part of an algorithm that calculates the coefficients in

$$O ( {N}^{\frac{3}{2}} )$$

calculations. Using the conventional fft, however, puts certain restrictions on how data can be sampled.

The conventional fft requires that data be collected at locations corresponding to a regular grid. A regular grid, in the two-dimensional case, is a set of locations all separated by a constant distance in both the first and second dimension. For example, in the planar case where the two dimensions are denoted by x and y, and the two increments are Δx and Δy, FIG. 4 illustrates a set of points on a regular grid. Because the fft algorithms restrict data to be measured on a regular grid, the mechanics in using physical scanners is also restricted. To reduce uncertainties, it is important that measurements be made at the exact locations on the grid. Large, heavy, multi-axis positioners are typically used to position the measurement probe accurately, thereby disadvantageously resulting in scans generally taking a long time to run in large part because the positioners are limited by how fast they can get to the regular grid points.

Measurements taken on a regular grid must satisfy certain sampling criterion. The inflexibility of the measurement locations, enforced by the data processing algorithms, generally requires that more data be collected than is necessary. It would be expected, for example, that a high gain antenna should be measured more densely at the locations where the intensity of the pattern is changing the fastest. Unfortunately, however, when measurements are taken on a regular grid, measurements may not be taken more densely in one location over another.

Another problem with mechanically scanning on a regular grid arises when multiple frequencies are required in the measurement. To get a complete set of data on the regular grid, the probe must come to a stop at each of the points to be measured. Multiple frequencies can then be measured at each location. Stopping and starting the probe at each measurement location is slow. Another method is to try and measure as many frequencies as possible at the regular grid points as the probe scans over that point. The data that are not taken at the regular grid locations are then compensated for by additional software routines, or errors due to small deviations of the points from the regular grid points are ignored. These additional complexities and uncertainties require careful attention.

Near-field measurements in spiral patterns have been developed for the planar, cylindrical, and spherical geometries. See D'Agostino, F., C. Gennarelli, G. Riccio, and C. Savarese. “Theoretical foundations of near-field-far-field transformations with spiral scannings.” Progress In Electromagnetics Research, PIER 61, pp. 193-214, 2006, the disclosure of which is hereby incorporated by reference herein. Such near-field measurements reliey on collecting data on a specific spiral pattern followed by interpolating to regular grid points. Standard techniques discussed above may then be used to calculate the necessary characteristic coefficients that determine far-field results. Measurement speeds are significantly faster because of the continuous scans. However, certain defects in the spherical geometry may exist due to issues with the interpolating functions in this geometry, and the restriction to a specific spiral pattern. Furthermore, when measurements are made at locations that are not exactly on the specific spiral pattern, additional position correcting software must be implemented. See D'Agostino, F. Ferrara, C. Gennarelli, R. Guerriero, and M. Migliozzi, “An iterative technique to compensate for positioning errors in the NF-FF transformation with helicoidal scanning for long antennas.” Progress In Electromagnetics Research C. vol. 18, pp. 73-86, the disclosure of each of which is hereby incorporated by reference herein.

Therefore, it is an object of this invention to provide an improvement which overcomes the aforementioned inadequacies of the prior art devices and provides an improvement which is a significant contribution to the advancement of the art of near field antenna measurement.

Another object of the invention is to take measurements on a non-uniform grid such that scanning may be done continuously over both axes, thereby eliminating the need for the axes to stop, which speeds up the overall measurement time. The method is not restricted to a particular path. Furthermore, if neither axes has to stop, there is no longer any concern with having to wait for the mechanical vibrations to ring out. Still further, once the need for the axes to stop is eliminated, a heavy measurement probe can be brought up to rotating at a constant speed and stay at that speed throughout the duration of the measurement.

Another object of the invention is to take measurement on a non-uniform grid such that that multiple frequencies may be taken simultaneously. In-between any two measurement points a plurality of frequencies can be measured, which do not need to be at any specific locations Provided that the location of the measurement at each frequency is recorded, the coefficients can be recovered.

Another object of the invention is to relax the restriction of having to do antenna scanning on a regular grid.

The foregoing has outlined some of the pertinent objects of the invention. These objects should be construed to be merely illustrative of some of the more prominent features and applications of the intended invention. Many other beneficial results can be attained by applying the disclosed invention in a different manner or modifying the invention within the scope of the disclosure. For example, the invention is also applicable of imaging whereby data taken off of the regular grid are used to construct images of a scene. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

For the purpose of summarizing this invention, this invention comprises an apparatus and method for measuring data over a two dimensional surface wherein data no longer has to be taken at the points located on a regular grid, two axes may be scanned over continuously to greatly increase the speed of measurements, in-between every two points taken during the scan, a plurality of frequency measurements may be collected because there is no restriction on the location of the points taken provided that certain conditioning requirements are satisfied, which are loosely based on the standard sampling requirements.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a fuller understanding of the nature and objects of the invention, reference should be had to the following detailed description taken in connection with the accompanying drawings in which:

FIG. 1 is a diagrammatic view of planar scanning;

FIG. 2 is a diagrammatic view of cylindrical scanning;

FIG. 3 is a diagrammatic view of spherical scanning;

FIG. 4 is a diagrammatic view of a regular grid;

FIG. 5 is diagrammatic view of planar scanning on a regular grid;

FIG. 6a is diagrammatic view of planar scanning on a non-regular sine wave grid;

FIG. 6b is diagrammatic view of planar scanning on a non-regular spiral grid;

FIG. 7 is diagrammatic view of cylindrical scanning on a regular grid;

FIG. 8 is diagrammatic view of cylindrical scanning on a non-regular grid;

FIG. 9 is diagrammatic view of spherical scanning on a regular grid;

FIG. 10 is diagrammatic view of cylindrical scanning on a non-regular grid;

FIG. 11 is diagrammatic view of multifrequency measurement;

FIG. 12 is block diagram of a antenna measurement system;

FIG. 13 is block diagram of an imaging system;

FIG. 14 is a block diagram of an exemplary controller that executes machine readable code for implementing the method of the invention;

FIG. 15 is a flow chart of the prior-art calculation of the characteristic coefficients;

FIG. 16 is a flow chart of the prior-art calculation of the characteristic coefficients taught by D'Agostino, et al's spiral pattern techniques; and

FIG. 17 is a flow chart of the new iterative techniques for calculating the characteristic coefficients based on measurements taken on generalized grids.

Similar reference characters refer to similar parts throughout the several views of the drawings.

### DETAILED DESCRIPTION OF THE PREFERRED EMBODIMENTS

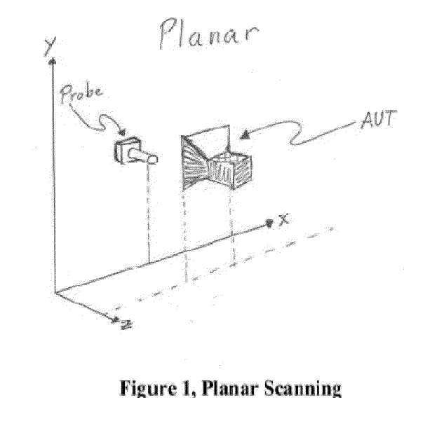

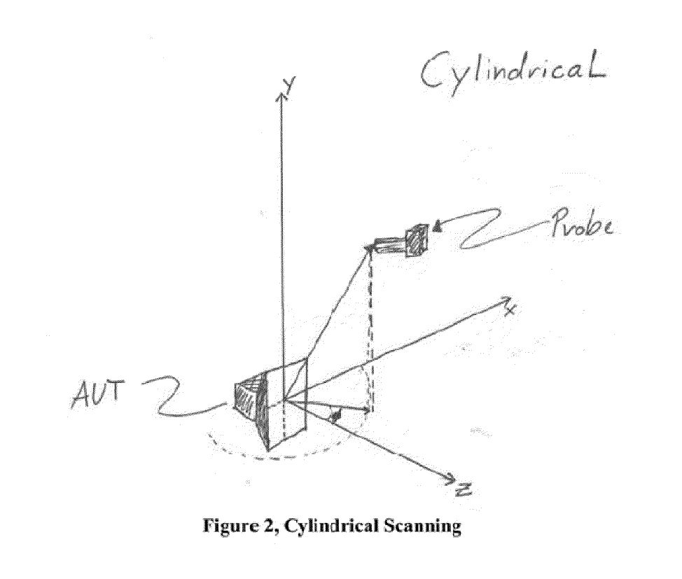

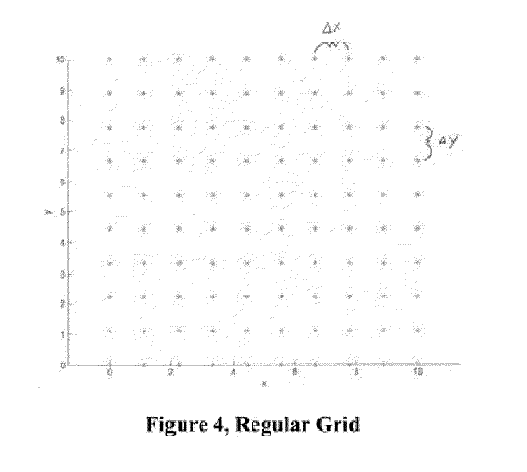

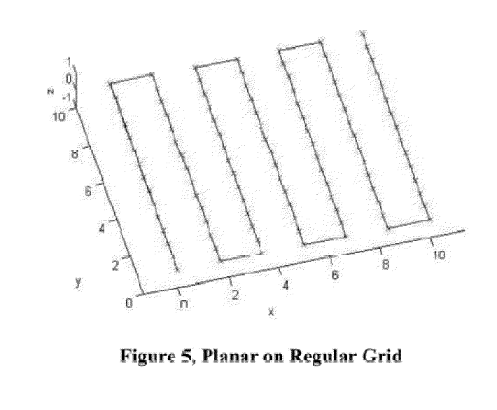

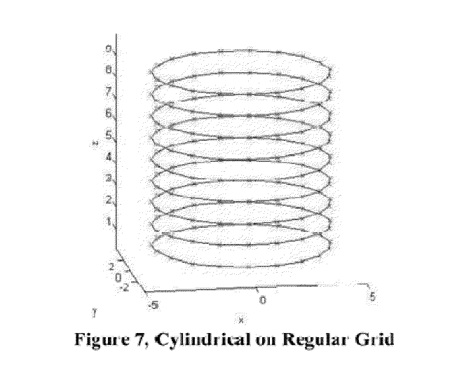

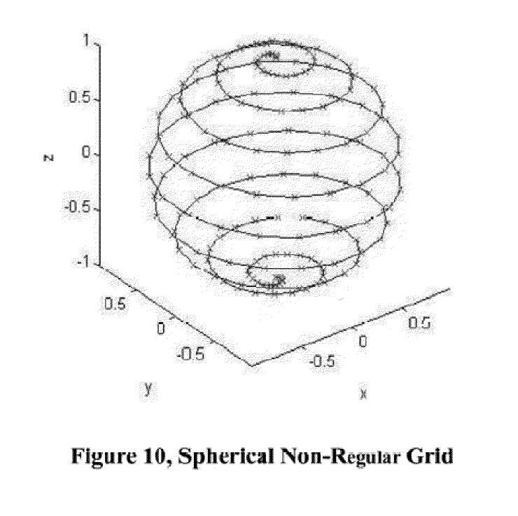

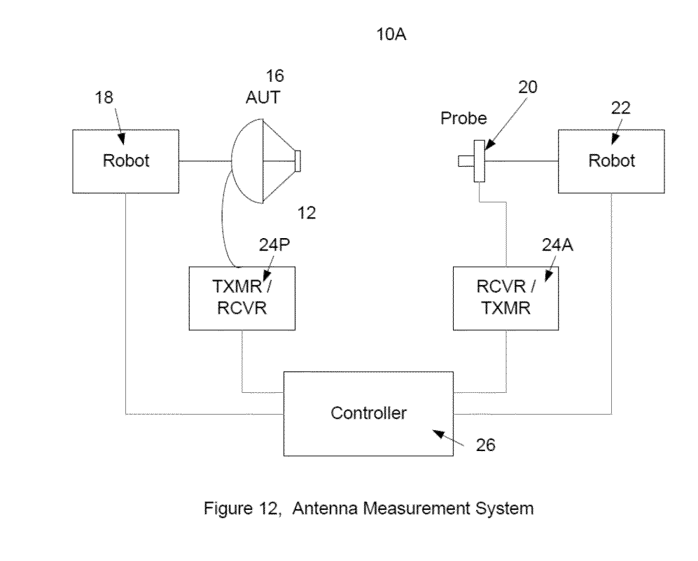

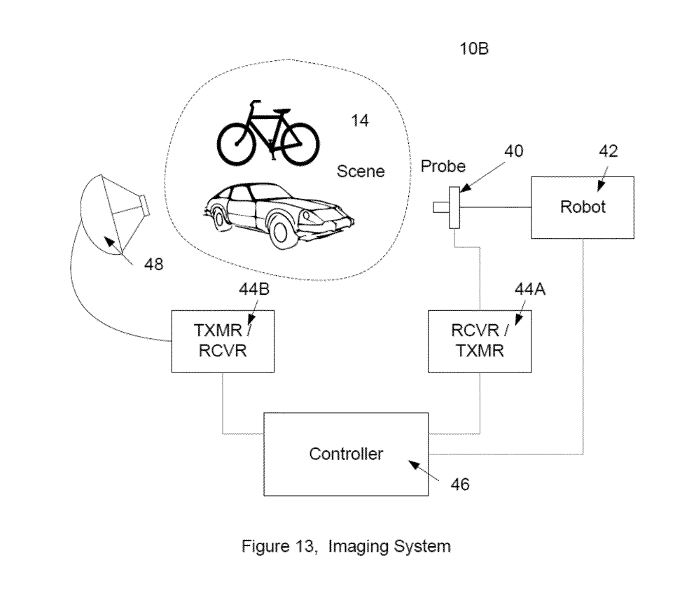

FIGS. 1-11 illustrate the method of the invention and FIGS. 12-13 illustrate the apparatus of the invention that may be employed for carrying out the method of the invention.

The invention has application in a variety of scanning systems 10. For example, as shown in FIG. 12 an antenna measurement system 10A measures antennas 12 whereas as shown in FIG. 13 an imaging system 10B measures scenes 14.

These scans obtained through the use of the systems 10 may collect scalar or vector data. However, it is noted that data is typically vector when the fields being measured are electromagnetic (FIG. 12) whereas data is typically scalar for acoustic measurements where pressure waves are measured with a probe such as a microphone.

Referring specifically to the antenna measurement system 10A of FIG. 12, in one embodiment, the system 10A comprises an Antenna Under Test 16 (AUT) controlled by a first robot 18 or it may remain stationary. A probe 20 is controlled by a second robot 22 or it may remain stationary. The respective robots 18 and 22 move the probe 20 and AUT 16 to scan over a two-dimensional surface in a three-dimensional space relative to each another. For example, in one operational configuration, the AUT 16 may remain stationary and the probe 20 may be moved by its robot 22 to scan over a two-dimensional surface in a three-dimensional space relative to the AUT 16. Alternatively, in a second operational configuration, the probe 20 may remain stationary and the AUT 16 may be moved by its robot 18 to scan over a two-dimensional surface in a three-dimensional space relative to the probe 20. Finally, in a third operational configuration, both the AUT 16 and the probe 20 may be moved by their respective robots 18 and 22, respectively, to move relative to another to scan over a two-dimensional surface in a three-dimensional space.

The probe 20 and the antenna 12 are respectively connected to a transceiver 24A and 24B comprising a receiver (RCVR) or a transmitter (TRMR) or both, depending on the scanning operational configuration employed. A controller 26 is interfaced to the robots 18 and 22 and the transceivers 24A and 24B.

The AUT 16 may be oriented by the first robot 18 at the speed and direction determined by the controller 26. The controller 26 directs the second robot 22 possibly in conjunction with the first robot 18 to move the probe 20 in a pattern to form a planar, cylindrical, or spherical pattern. The controller 26 collects data from the transceivers 24 and correlates it with the position of the probe 20 and the test signal. This information is then used by the controller 26 to determine the characteristic coefficients using the iterative method described herein. The antenna parameters are then determined.

Referring specifically to the imaging system 10B of FIG. 13, in a second embodiment the system 10 comprises a scene 14. Similar to the antenna measurement system of FIG. 12, a probe 40 is displaced from the scene 14. Connected to the probe 40 is a robot 42 for positioning the probe 40. The probe 40 is moved about by the robot 42 to scan over a two-dimensional surface in a three-dimensional space. The probe 40 is connected to a transceiver 44 comprising a receiver (RCVR) or a transmitter (TRMR) or both. The transceiver 44 is connected to a controller 46. An illuminating antenna 48 may be employed to illuminate the scene 14.

The controller 46 directs the robot 42 to position the probe 40 in a pattern to form a planar, cylindrical, or spherical pattern. The controller 46 collects data from the transceiver 44 and correlates it with the position of the probe 40 and the test signal. This information is then used by the controller 46 to determine the characteristic coefficients using the iterative method described herein. An image of the scene 14 is then determined.

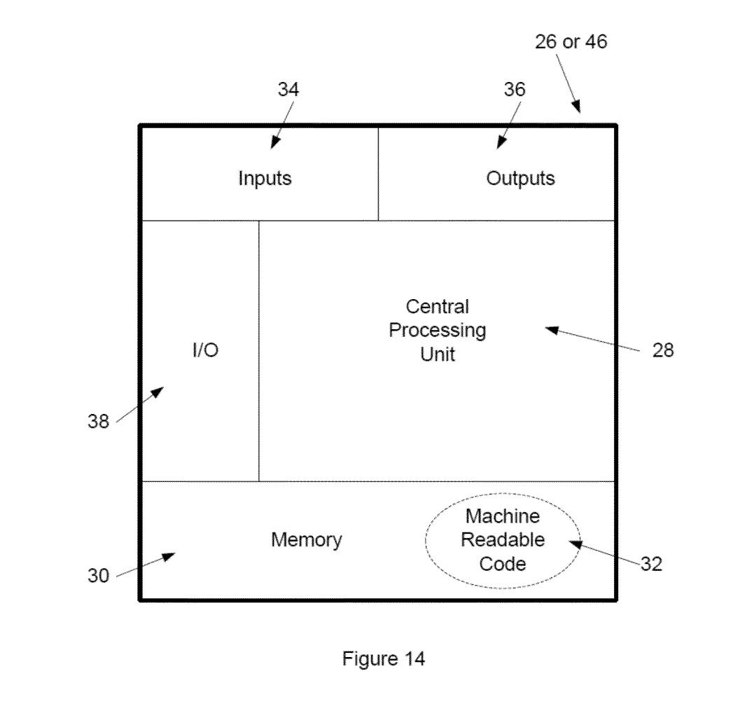

As shown in FIG. 14, controller 26 or 46 may comprise a central processing unit (CPU) 28, memory 30 storing machine-readable code 32 to be executed by the CPU 28 to implement the method of the invention, and inputs 34 and outputs 36 interfaced to the AUT 16/probe 20 (or probe 40) and their robots 18/22 (or probe 40). It is noted that without departing from the spirit and scope of this invention, one or more of such components of the controller 26 or 46 may all reside on a single integrated circuit or may reside in application-specific integrated circuits (ASIC) or programmable circuits such as complex programmable logic devices (CPLD) or field-programmable gate arrays (FPGA). It should also be noted that without departing from the spirit and scope of the invention, the controller 26 or 46 may include conventional input/outputs (I/O) 38 for interfacing to conventional input devices (keyboard, a mouse, etc.) and output devices (printer, plotter, computer screen, magnetic tape, removable hard disk, USB port, etc.).

While FIG. 13 shows the controller 26 or 46 as a particular configuration of hardware and software, any configuration of hardware and software, as would be known to a person of ordinary skill in the art, may be utilized for the purpose of carrying out the method of the invention as described below.

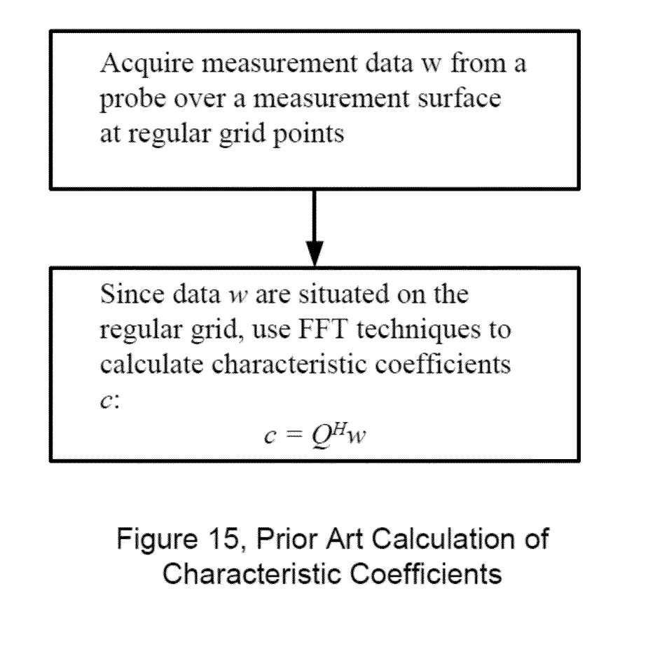

FIG. 15 is a flow chart showing the high level steps to a prior-art method of calculating characteristic coefficients from measurement data acquired on a regular grid. In the first step measurement data is obtained from a measurement probe over a measurement surface where measurements are sampled at points on a regular grid to generate a set of measurement data, w. In a next step, the characteristic coefficients are calculated base upon the data sampled on a regular grid using known FFT techniques.

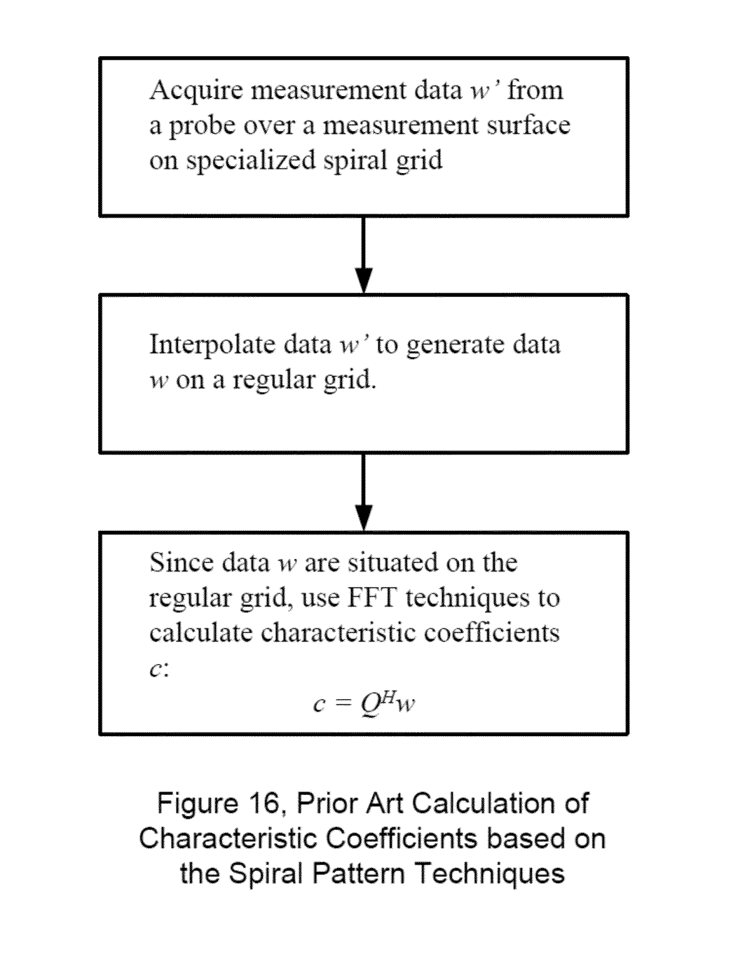

FIG. 16 is a flow chart showing the high level steps to a prior-art method of calculating characteristic coefficients from measurement data acquired on a specialized spiral grid. In a first step measurement data is obtained from a measurement probe over a measurement surface where measurement are sampled at points on a specialized spiral grid to generate a set of measurement data, w′. In a next step, an interpolation process is used to generate data w that is positioned on a regular grid based upon the measurement data w′. Finally, the characteristic coefficients are calculated base upon the data w which lies on a regular grid using known FFT techniques.

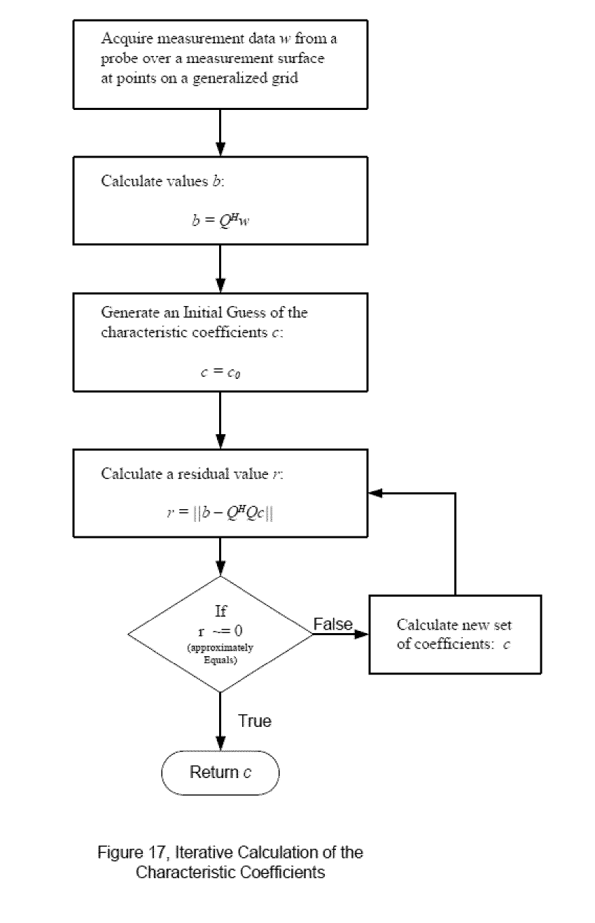

FIG. 17 is a flow chart showing a high level set of steps representative of one embodiment of the invention. The follow chart shows a representative, iterative method of calculating characteristic coefficients from measurement data acquired on a generalized grid. In a first step, a set of measurement data, w, is acquired over a measurement surface at points on a generalized grid. In a next step an intermediate value b is computed from the measured data values, w. In another step an initial guess of the characteristic coefficients is generated. In another step a residual value, r, is calculated based upon the difference between the value b, and a value based upon the estimated characteristic coefficients. If the residual value is approximately zero then the estimated characteristic coefficients, c, are the desired characteristic coefficients. If r is not close to zero a new set of estimated characteristic coefficients are computed and the iterative process is repeated.

For ease in better understanding the method of the invention, the non-uniform sampling algorithm is first described in planar geometry. For the cylindrical and spherical geometries, the algorithms are similar and can be understood with slight modification to the discussion below. See Wittmann, R. C.; Alpert, B. K.; Francis, M. H., “Near-field antenna measurements using nonideal measurement locations,” Antennas and Propagation, IEEE Transactions on, vol. 46, no. 5, pp. 716-722, May 1998 doi: 10.1109/8.668916 URL:http://ieeexplore.ieee.org/stamp/stamp.jsp?tp=&arnumber=668916&isnumber=146 41, the disclosure of which is hereby incorporated by reference herein.

For the sake of simplicity, the algorithms are given assuming the measured data is scalar. Extending the theory to the vector case is straight forward, but the details are not necessary for understanding the following algorithm. As noted above, it should be noted here that this technology is not restricted to the vector case; it is also applicable to the scalar case where it can be used, for example, in acoustic scanning

The response w(r) of a probe (see discussion above for definition of probe-response) located at r can be approximated as a band-limited sum of planewaves:

$$w ( r ) • {\sum }_{n = 0}^{{P}_{1} - 1} {\sum }_{m = 0}^{{P}_{2} - 1} {c}_{n m} exp ( i {k}_{nm} \cdot r ) \\ where \\ {k}_{nm} = \frac{π n}{{L}_{x}} \hat{x} + \frac{π m}{{L}_{y}} \hat{y} + {γ}_{nm} \hat{z} \\ and \\ {γ}_{nm} ≡ \sqrt{{k}^{2} - {( \frac{π n}{{L}_{x}} )}^{2} - {( \frac{π m}{{L}_{y}} )}^{2}} \qquad ( 1.2 )$$

In the above equations, the characteristic cₙₘ coefficients are the N=P₁P₂ unknowns of the system. The band limits P₁ and P₂ are chosen so that the representation (1.2) satisfies the desired level of accuracy in the region of interest. From the coefficients c_{nm all the key antenna parameters, such as the antenna pattern, directivity, gain, etc. may be determined by well-known methods.}

To solve for the coefficients numerically, the probe response w(r) is sampled at the discrete locations rₖ. Equation (1.2) can now be written in matrix form:

w=Qc (1.3)

were w≡{w(rₖ)}, c≡{cₙₘ}, and Q≡{exp(ikₙₘ·rₖ)}. Solving for the coefficients c becomes a linear algebra problem, and any standard numerical technique can be used to find c (Gaussian elimination for example).

The form of equation (1.2), a two-dimensional Fourier series, makes solving equation (1.3) possible using fast algorithms. Provided that w≡{w(rₖ)} is sampled at locations on a regular grid within the plane, equation (1.3) has the structure that allows it to be solved with the fast Fourier transform (fft) algorithm. See Section 4.6.4 in Golub, Gene H., and Loan Charles F. Van, Matrix Computations. Baltimore, Md.: Johns Hopkins U P, 1989, the disclosure of which is hereby incorporated by reference herein. On regular grid points, the inverse of Q is simply the Hermitian transpose Q^{H} (i.e., Q^{H}Q=I), thus the solution for c is

Q^{H}w=c

Applying Q^{H} to w can be done in O(N log N) operations when the fft algorithm is employed. This is the standard method of solving equation (1.3) in the industry because of the tremendous computational efficiency of the fft algorithm. In the past, certain important measurements could not have been done otherwise. Computational efficiency has been very important to near-field measurements; the fft algorithm (used not only in planar measurements, but in cylindrical and spherical as well) has restricted measurements to be made on regular grid points. By the advent of the unequally spaced fast Fourier transform (see Dutt, A., and Rokhlin, V., “Fast Fourier transforms for nonequispaced data,” SIAM J. Scientific Computing, vol. 14, pp. 1369-1393, November 1993, the disclosure of which is hereby incorporated by reference herein) this restriction is now lifted.

The unequally spaced fast Fourier transform (ufft) is a fast algorithm used to apply the matrix Q to a vector of coefficients c in O(N log N) operations even when rₖ are not located at points on a regular grid. The equation (1.3), however, cannot be inverted simply by multiplying both sides of the equation by the Hermitian transpose; Q^{H} is not the inverse of Q (i.e., Q^{H}Q≠I) when rₖ are off the regular grid. Another method must be used to solve for the coefficients in c.

To solve for c, the normal equations are constructed by applying the Hermitian transpose to both sides of equation (1.3):

Q^{H}w=Q^{H}Qc (1.4)

The solution of this equation for c minimizes ∥w−Qc∥₂, thus, c is a solution to the above matrix equation in the least squares sense. Computationally, constructing the normal equations allows us to solve for c using certain iterative methods. For an iterative method to be useful here, solving for in equation (1.4) must be faster than solving equation (1.3) using a standard technique such as Gaussian elimination. It has been found that using a particular iterative technique in conjunction with the ufft on data taken off the regular grid provides an algorithm that has a similar computational complexity as using the fft to solve equation (1.3) when data is on the regular grid. See Wittmann et al (1998).

A preferred method of solving the normal equations (1.4) is using the Conjugate Gradient Method. The Conjugate Gradient Method is an iterative technique that takes advantage of the fact that Q^{H}Q is Hermitian, and positive definite. See Golub et al. Using the Conjugate Gradient Method and applying Q^{H} and Q by direct sums, the coefficients c can be determined in O(NV²) operations per iteration. This is significantly better than solving for the coefficients using a method like Gaussian eliminations (which takes O(N²) operations) provided that the Conjugate Gradient Method converges fast enough.

Solving for the coefficients c can be made even more efficient if the Conjugate Gradient Method is used in conjunction with the unequally spaced fast Fourier transform. See Dutt, A., and Rokhlin V., “Fast Fourier transforms for nonequispaced data,” SIAM J. Scientific Computing, vol. 14, pp. 1369-1393, November 1993, the disclosure of which is hereby incorporated by reference herein. Using this fast algorithm, both Q^{H} and Q can be applied in O(N log N) operations rather than the O(N²) operations used by applying these linear operators by direct sums. The total complexity using this unequally spaced fast Fourier transform and the Conjugate Gradient Method provides an algorithm that solves for the coefficients c in O(N log N) operations.

The basic steps for solving equation (1.4) for the antenna characteristic coefficients, using the Conjugate Gradient Method, are (refer to Algorithm 10.2.1 in Golub, et al and Section III of Wittmann (1998), et al, the disclosures of which are hereby incorporated by reference herein:
1. Set:

A≡Q^{H}Q

b≡Q^{H}w

r₀=b−Ac₀
where c₀ is an intial estimate for the coeffients . . . which can be zero, and r is the residual vector which will be driven to zero.
2. Create an iterative loop over k while ∥r∥>ε (epsilon is a small terminating condition value). In each iteration of the loop perform the operations:

$$\begin{matrix}{p}_{k} = {r}_{k - 1} + \frac{{‖ {r}_{k - 1} ‖}^{2}}{{‖ {r}_{k - 2} ‖}^{2}} {p}_{k - 1} & a ) \\ z = {Ap}_{k} & b ) \\ {α}_{k} = \frac{{‖ {r}_{k - 1} ‖}^{2}}{{p}_{k}^{H} z} & c ) \\ {c}_{k} = {c}_{k - 1} + {α}_{k} {p}_{k} & d ) \\ {r}_{k} = {r}_{k - 1} - {α}_{k} z & e )\end{matrix}$$

In the first iteration of the loop, step (a) is replaced with: p₁=r₀. In step (b) the matrix A is applied to the vector pₖ. If normal matrix multiplication is used in this step, the number of operations is O(N²). In the preferred embodiment, the unequally spaced fast Fourier transform (see Dutt, et al) is used for these operations, thus A is applied in O(N log N) operations.

The speed at which the Conjugate Gradient Method converges depends on the conditioning of Q^{H}Q. See Wittmann, et al (1998). It is also shown in Wittmann's paper that the conditioning can be markedly improved if the data is weighted. Although the above discussion is specific to planar scanning, the same method works in both the cylindrical and spherical geometries as well. In cylindrical scanning, the unequally spaced fast Fourier transform can be used to make both Q^{H} and Q applicable in O(N log N) operations. In the cylindrical geometry Q maps the coefficients of a cylindrical harmonic expansion to the probe response measurements. The overall order of operations in cylindrical scanning is O(N log N). In spherical scanning, the unequally spaced fast Fourier transform can be used to make both Q^{H} and Q applicable in

$$O ( {N}^{\frac{3}{2}} )$$

operations. The operator Q maps the coefficients of a spherical harmonic expansion to the probe response measurements. The overall order of operations in spherical scanning is

$$O ( {N}^{\frac{3}{2}} ) .$$

The spherical case is described more completely in Wittmann, R. C.; Alpert, B. K.; Francis, M. H., “Near-field, spherical-scanning antenna measurements with nonideal probe locations,” Antennas and Propagation, IEEE Transactions on, vol. 52, no. 8, pp. 2184-2187, August 2004 doi: 10.1109/TAP.2004.832316 URL: http://ieeexplore.ieee.org/stamp/stamp/jsp?tp=&arnumber=1321354&isnumber=29268, the disclosure of which is hereby incorporated by reference herein; the algorithm there also includes probe correction and data weighting.

The need for fast algorithms has restricted the locations at which measurements can be made in antenna scanning In the past several decades, sophisticated and highly precise robotics have been developed with the goal to perform antenna scans over regular grids as fast and as precise as possible. Mechanically, at least two axes are used to position the measuring probe and the AUT in these measurements. See Chapter 7 of Slater, et al, for the details behind building precision robots for antenna scanning Restricting measurements to regular grid points places serious restrictions on how fast and precise mechanical positioners can be made to do antenna measurements.

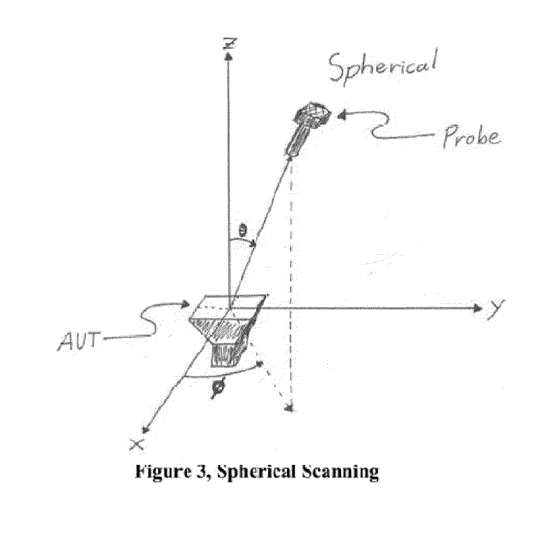

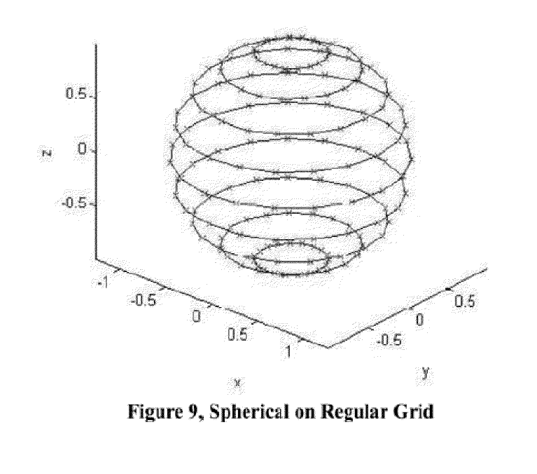

In the industry, it is common place to scan continuously over one axis and to step in another. In spherical scanning, for example, one method for obtaining the probe response over the entirety of the sphere is to rotate the AUT mechanically about the phi directions continuously (see FIG. 9). After the antenna has been ramped up in speed in the phi direction (see FIG. 3 for the coordinate system), the probe takes measurements at regularly spaced points until the antenna has been rotated 360 degrees. After this, the antenna stops rotating and the probe is then stepped in the theta direction. The antenna starts rotating in the phi direction again and the processes is repeated until all the data needed has been collected (see FIG. 9). Mechanically this is a slow process because of all the starting and stopping. It takes time for the antenna to be ramped up in speed and time for it to be stopped. It also takes time to step the probe in the theta direction. The complexity of the control systems to position the probe is high because the system has to move heavy positioners as quickly and as precisely as possible. Also, moving the positioners in a jolting fashion causes wear and tear.

Using the efficient algorithms discussed above, a method for alleviating the above problems using continuous scanning is described as follows. Because efficient algorithms for computing the coefficients cₙₘ exist for the standard geometry's (planar, spherical, and cylindrical), scanning is no longer restricted to the regular grid. In the proposed method, scanning is done continuously over the axes and the measurement grid is non-regular and possibly non-uniform. For example, in the spherical case, once the antenna is ramped up to speed in the phi direction, it may remain in motion for the duration of the scan as the probe is continuously scanned over the theta direction. As the probe is scanned over the surface of the sphere, measurements are taken periodically until enough data is acquired to use in the algorithm discussed. The pattern of the scan may look as it does in FIG. 9; however, the method is not limited to this particular pattern. Because the axes no longer have to be started and stopped throughout the duration of the scan, the total scan time will be significantly smaller. The control system used for positioning is also much less complex for continuous scanning and there is not as much wear and tear on the mechanical system.

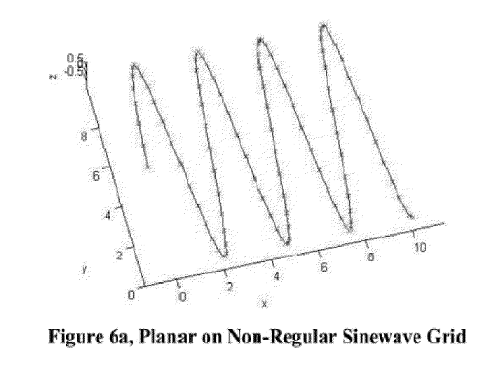

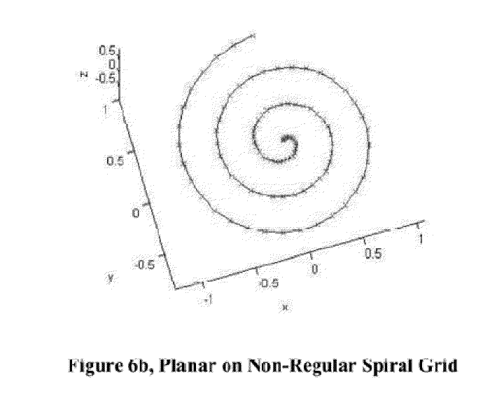

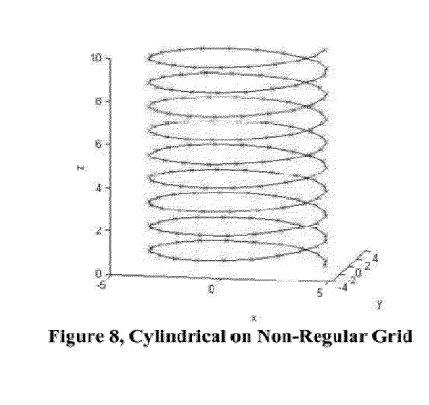

Continuous scanning also applies to the cylindrical and planar cases too. FIGS. 6a and 6b show possible continuous scan patterns for the planar case. FIG. 8 shows a possible continuous scan patterns for the cylindrical case.

The method of the invention relaxes the restriction of having to do antenna scanning on a regular grid because it is based on intelligently searching for a set of characteristic coefficients (as seen in Equation 1.1) in an iteration scheme. The method of the invention is therefore fundamentally different from the technique taught by D'Agostino et al. More specifically, the method of the invention starts with a guess for the coefficients and searches for a set of coefficients that satisfy Equation 1.1 in a least squared since, whereas the technique taught by D'Agostino et al starts from data taken on a spiral, interpolate to a regular grid and then uses the standard techniques to obtain the characteristic coefficients. The method of the invention is additionally enhanced by the development of the unequally spaced fast Fourier transform as taught in Dutt, A., and Rokhlin, V., “Fasi Fourier transforms for nonequispaced data,” SIAM J. Scientific computing, vol. 14, pp. 1369-1393, November 1993, the disclosure of which is hereby incorporated by reference herein. The method of the invention also relaxes the restriction of having to do antenna scanning on a specific spiral. The order of the number of operations it takes to compute the characteristic coefficients using the unequally spaced Fourier transform is similar to prior techniques, making computation times reasonable.

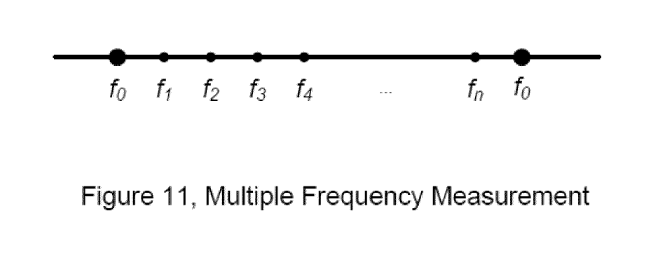

Another problem with prior art has to do with scanning the probe response for multiple frequencies. Several methods can be considered. First, the full scan can be done multiple times, each at a different frequency. This means that if there are N frequencies, then the measurement will take at least N times as long as it would take for just one frequency. Another method is to stop at each measurement location, with no continuous scanning over either axis. This also takes much more time than it takes to measure a single frequency because the whole system must stop at each measurement location while the different frequencies are being measured. If only a few frequencies are desired, scanning can be done in the same way it is usually done for the single frequency; at each measurement location each of the frequencies are measured as quickly as possible around the neighborhood of the desired location. The measurement is done in the same amount of time as the single frequency scan, but the process adds complexities to the software and adds uncertainties due to not measuring at the precise measurement points. An improved method for measuring multiple frequencies during a scan using the algorithms discussed above in accordance with the method of the invention is described as follows. Because there is no longer a need to measure at the exact locations on a regular grid, multiple frequencies can be measured between any two measurement points taken in the scan. For example, if two points measured over a scan (such as the one discussed above on a sphere) are denoted by x₁ and x₂, and at these points the frequency f₀ is measured, then any number of frequencies between these two measurements can be sampled as long as their corresponding positions are known (see FIG. 11). The maximum number of frequencies that can be taken is determined by how fast the receiver can measure these frequencies, the speed of the scan, and how close the two points x₁ and x₂ are from one another. With this method, a lot of frequencies can be measured over the measurement surface in the same time it takes to measure a single frequency over the surface.

If an antenna pattern is known to change slowly in some regions of the measured surface, and faster in other regions of the measured surface, the measurement sample pattern can be adapted to the expected antenna characteristic. A non-uniform sampling is used, whereby sampling is sparse in the regions where the antenna pattern changes slowly, and the sampling is denser in the regions where the antenna pattern changes rapidly. The non-uniform sampling algorithm covered in section 4 is used to compute the antenna characteristics. This method may be combined with continuous-two-axis scanning and it may be combined with sampling multiple frequencies outlined above.

In summary, as may be appreciated from the foregoing description, the method of the invention comprises a scanning measurement system that is no longer restricted to regular grid points by certain fast algorithms. The method of the invention comprises scanning systems such as near-field antenna measurements, far-field antenna measurements, acoustic measurements, and imaging systems. One aspect of the invention is continuously scan over the planar, cylindrical, and spherical surfaces to recover the coefficients cₙ in the expansion

$$w ( r ) = {\sum }_{n = 0}^{N} {u}_{n} {c}_{n} {ϕ}_{n} ( r )$$

where w(r) is the measured probe-response (electromagnetic or acoustic) uₙ is a weighting function, and we are able to do so efficiently. The characteristic coefficients cₙ of the system may be used to calculate antenna parameters during near-field scanning, to calculate microphone parameters during acoustic scanning, and to form images during imaging.

For the purpose of the appended claims, the set of all points is defined as “generalized grid points.” Generalized grid points include non-regular grid points and, optionally, regular grid points. Accordingly, the method of the invention allows measurements at non-regular grid points, as well as regular grid points.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and operation and the combination and arrangement of components and steps of the method may be resorted to without departing from the spirit and scope of the invention.

Now that the invention has been described,

What is claimed is:

1. A scanning measurement system comprising in combination:
a device under test for receiving or transmitting a signal;
a measurement probe;
a robot for moving said device or said probe relative to one another to scan continuously over a two-dimensional surface in a three-dimensional space;
a controller for obtaining measurement samples at generalized grid points on the said two-dimensional surface computing characteristic coefficients from said measured values.

2. The system as set forth in claim 1, wherein said two-dimensional surface is planar.

3. The system as set forth in claim 1, wherein said two-dimensional surface is cylindrical.

4. The system as set forth in claim 1, wherein said two-dimensional surface is spherical.

5. The system as set forth in claim 1, wherein said characteristic coefficients are recovered using a conjugate gradient method.

6. The system as set forth in claim 1, wherein said characteristic coefficients are recovered using in part an unequally spaced fast Fourier transform.

7. The system as set forth in claim 1, wherein said characteristic coefficients are recovered using a conjugate gradient method and an unequally spaced fast Fourier transform.

8. A scanning measurement system comprising in combination:
a device under test for receiving or transmitting a signal:
a measurement probe;
a robot for moving said device or said probe relative to one another to scan continuously over a two-dimensional surface in a three-dimensional space;
a controller for obtaining measurement samples at a plurality of frequencies on a generalized grid on the said two-dimensional surface to compute characteristic coefficients at a plurality of frequencies from said measured values on said generalized grid.

9. The system as set forth in claim 8, wherein said two-dimensional surface is planar.

10. The system as set forth in claim 8, wherein said two-dimensional surface is cylindrical.

11. The system as set forth in claim 8, wherein said two-dimensional surface is spherical.

12. The system as set forth in claim 8, wherein said probe is scanned continuously over a two-dimensional surface in a three-dimensional space.

13. The system as set forth in claim 8, wherein said characteristic coefficients of the device are recovered at a plurality of frequencies using the conjugate gradient method at each frequency.

14. The system as set forth in claim 8, wherein said characteristic coefficients are recovered at a plurality of frequencies using in part an unequally spaced fast Fourier transform.

15. The system as set forth in claim 8, wherein said characteristic coefficients are recovered using the conjugate gradient method and an unequally spaced fast Fourier transform.

16. A method for scanning, comprising the steps of:
sampling an antenna radiation pattern on a two-dimensional surface in a three-dimensional space;
measuring samples on a generalized grid on the said two-dimensional surface; and
computing antenna characteristics from said measuring samples.

17. The method as set forth in claim 16, wherein said two-dimensional surface is planar.

18. The method as set forth in claim 16, wherein said two-dimensional surface is cylindrical.

19. The method as set forth in claim 16, wherein said two-dimensional surface is spherical.

20. The method as set forth in claim 16, wherein said characteristic coefficients are recovered using a conjugate gradient method.

21. The method as set forth in claim 16, wherein said characteristic coefficients are recovered using in part an unequally spaced fast Fourier transform.

22. The method as set forth in claim 16, wherein said characteristic coefficients are recovered using a conjugate gradient method and an unequally spaced fast Fourier transform.

23. A method for scanning, comprising the steps of:
sampling a radiation pattern on a two-dimensional surface in a three-dimensional space;
obtaining measurement samples at a plurality of frequencies on said generalized grid on the said two-dimensional surface to compute characteristic coefficients at a plurality of frequencies from said measured values on said generalized grid; and
computing characteristics from said measuring samples.

24. The method as set forth in claim 23, wherein said two-dimensional surface is planar.

25. The method as set forth in claim 23, wherein said two-dimensional surface is cylindrical.

26. The method as set forth in claim 23, wherein said two-dimensional surface is spherical.

27. The method as set forth in claim 23, wherein said probe is scanned continuously over a two-dimensional surface in a three-dimensional space.

28. The method as set forth in claim 23, wherein said characteristic coefficients of the device are recovered at a plurality of frequencies using the conjugate gradient method at each frequency.

29. The method as set forth in claim 23, wherein said characteristic coefficients are recovered at a plurality of frequencies using in part an unequally spaced fast Fourier transform.

30. The method as set forth in claim 23, wherein said characteristic coefficients are recovered using the conjugate gradient method and an unequally spaced fast Fourier transform.
